(19) United States
(12) Patent Application Publication
(10) Pub. No.: US 2022/0115418 A1
(43) Pub. Date: Apr. 14, 2022

(54) PHOTO SENSOR ELEMENT

(71) Applicant: Au Optronics Corporation, Hsinchu (TW)

(72) Inventors: Cheng-Hsing Lin, Hsinchu (TW); Shu-Wen Tzeng, Hsinchu (TW)

(73) Assignee: Au Optronics Corporation, Hsinchu (TW)

(21) Appl. No.: 17/234,730

(22) Filed: Apr. 19, 2021

(30) Foreign Application Priority Data
Oct. 14, 2020 (TW) 109135455

(51) Int. Cl. H01L 27/146

(52) U.S. Cl. CPC H01L 27/1461; H01L 27/14612; H01L 27/14643

(57) ABSTRACT

A photo sensor element, including a substrate, a first electrode, a second electrode, and a photosensitive layer, is provided. The first electrode is located on the substrate and has multiple first openings. The second electrode overlaps the first electrode and the first openings. The photosensitive layer is sandwiched between the first electrode and the second electrode, and overlaps the first electrode and the second electrode.

### CROSS-REFERENCE TO RELATED APPLICATION

This application claims the priority benefit of Taiwan application serial no. 109135455, filed on Oct. 14, 2020. The entirety of the abovementioned patent application is hereby incorporated by reference herein and made a part of this specification.

### BACKGROUND

### Technical Field

This disclosure relates to a photo sensor element.

### Description of Related Art

Currently, in order to increase convenience during product usage, many manufacturers have installed photo sensor elements in their products. For example, a photo sensor element with fingerprint recognition function is often embedded in existing mobile phones. In the conventional fingerprint recognition technology, the photo sensor element detects the light reflected by the fingerprint of the finger. Intensities of reflected light corresponding to the ridges and furrows of the fingerprint are different. Therefore, the different light intensities enable the sensing device to generate currents of different magnitudes, thereby distinguishing the shape of the fingerprint.

### SUMMARY

The disclosure provides a photo sensor element, which has a low capacitance value and good photosensitivity.

A photo sensor element is provided, according to at least one embodiment of the disclosure. The photo sensor element includes a substrate, a first electrode, a second electrode and a photosensitive layer. The first electrode is located on the substrate and has multiple first openings. The second electrode overlaps the first electrode and the first openings. The photosensitive layer is sandwiched between the first electrode and the second electrode, and overlaps the first electrode and the second electrode.

To make the abovementioned more comprehensible, several embodiments accompanied by drawings are described in detail as follows.

### BRIEF DESCRIPTION OF THE DRAWINGS

FIG. 1A is a schematic top view of a photo sensor element according to an embodiment of the disclosure.

FIG. 1B is a schematic cross-sectional view taken along a line A-A′ in FIG. 1A.

FIG. 1C is a schematic cross-sectional view taken along a line B-B′ in FIG. 1A.

FIG. 2A is a schematic top view of a photo sensor element according to an embodiment of the disclosure.

FIG. 2B is a schematic cross-sectional view taken along a line A-A′ in FIG. 2A.

FIG. 2C is a schematic cross-sectional view taken along a line B-B′ in FIG. 2A.

FIG. 3 is a schematic top view of a photo sensor element according to an embodiment of the disclosure.

FIG. 4 is a schematic top view of a photo sensor element according to an embodiment of the disclosure.

FIG. 5 is a schematic top view of a photo sensor element according to an embodiment of the disclosure.

FIG. 6 is a schematic top view of a photo sensor element according to an embodiment of the disclosure.

### DESCRIPTION OF THE EMBODIMENTS

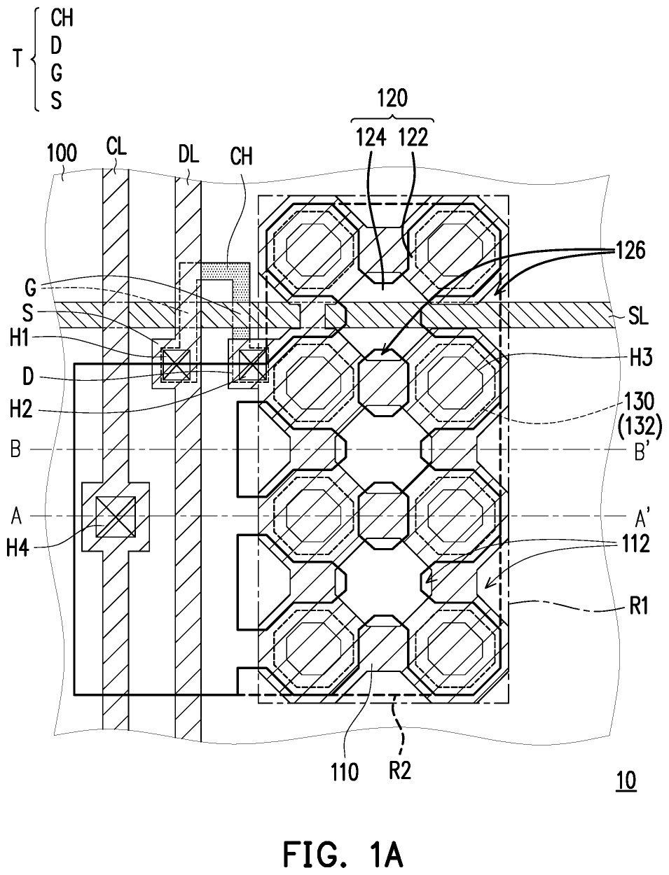

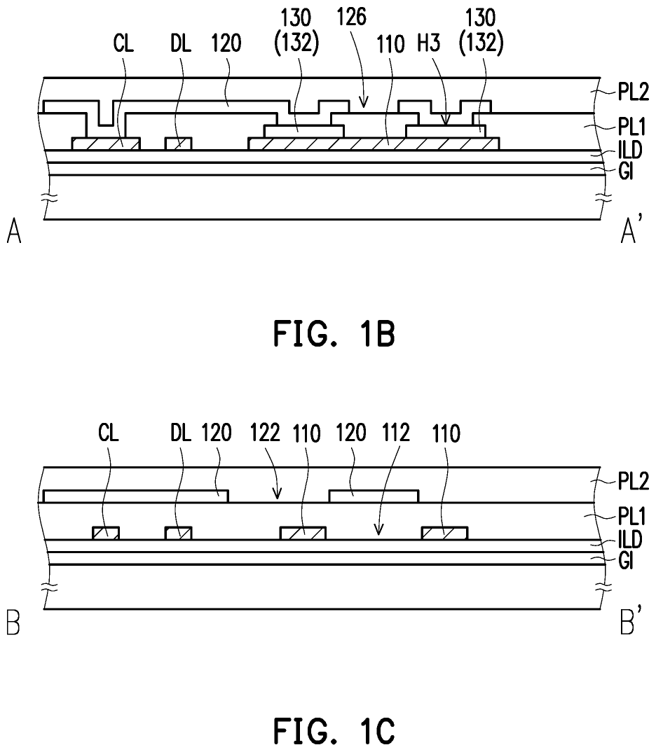

FIG. 1A is a schematic top view of a photo sensor element according to an embodiment of the disclosure. FIG. 1B is a schematic cross-sectional view taken along a line A-A′ in FIG. 1A. FIG. 1C is a schematic cross-sectional view taken along a line B-B′ in FIG. 1A.

With reference to FIGS. 1A, 1B, and 1C, a photo sensor element 10 includes a substrate 100, a first electrode 110, a second electrode 120, and a photosensitive layer 130. In the embodiment, the photo sensor element 10 further includes a scan line SL, a data line DL, a signal line CL, and an active element T.

The active element T is located on the substrate 100. The active element T includes a gate G, a semiconductor layer CH, a source S and a drain D. The gate G is electrically connected to the scan line SL. The semiconductor layer CH overlaps the gate G, and a gate insulation layer GI is sandwiched between the semiconductor layer CH and the gate G. In some embodiments, the semiconductor layer CH, the gate insulation layer GI, and the gate G are sequentially stacked on the substrate 100. An interlayer dielectric layer ILD is located on the gate G and the gate insulation layer GI. The source S and the drain D are located on the interlayer dielectric layer ILD. The source S is electrically connected to the data line DL and the semiconductor layer CH. In the embodiment, the source S is directly connected to the data line DL, and is electrically connected to the semiconductor layer CH through a via hole H1 that penetrates the interlayer dielectric layer ILD and the gate insulation layer GI. The drain D is electrically connected to the semiconductor layer CH and the first electrode 110 directly or indirectly. In the embodiment, the drain D is directly connected to the first electrode 110, and is electrically connected to the semiconductor layer CH through a via hole H2 that penetrates the interlayer dielectric layer ILD and the gate insulation layer GI.

In the embodiment, the active element T is a top-gate type thin film transistor, but the disclosure is not limited thereto. In other embodiments, the gate G may also be located below the semiconductor layer CH, so that the active element T is a bottom-gate type thin film transistor. In addition, an ohmic contact layer may be optionally included between the source S and the semiconductor layer CH, and between the drain D and the semiconductor layer CH, so as to enhance electrical connection between the source S and the semiconductor layer CH, and between the drain D and the semiconductor layer CH.

In the embodiment, the gate G and the scan line SL belong to a same conductive patterned layer, and are directly connected to each other, but the disclosure is not limited thereto. In the embodiment, materials of the gate electrode G and the scan line SL include metals such as chromium, gold, silver, copper, tin, lead, hafnium, tungsten, molybdenum, neodymium, titanium, tantalum, aluminum, and zinc, alloys of the above metals, oxides of the above metals, nitrides of the above metals, or a combination of the above, or other conductive materials.

In the embodiment, the signal line CL, the data line DL, the source S, the drain D and the first electrode 110 belong to a same conductive patterned layer, and a material of the layer includes metals such as chromium, gold, silver, copper, tin, lead, hafnium, tungsten, molybdenum, neodymium, titanium, tantalum, aluminum, zinc, alloys of the above metals, oxides of the above metal, nitrides of the above metal, or a combination of the above, or other conductive materials.

The first electrode 110 is located on the substrate 100 and has multiple first openings 112. The first openings 112 may be configured to reduce a surface area of the first electrode 110 and reduce a total capacitance value of the photo sensor element 10. For example, a surface area of the first electrode 110 and the first openings 112 totals to R1. Since the surface area of the first openings 112 is greater than 0, the surface area of the first electrode 110 is less than R1.

The photosensitive layer 130 is located on the first electrode 110. In some embodiments, the photosensitive layer 130 includes multiple photosensitive patterns 132 that are separated from each other, whereby the separated photosensitive patterns 132 may reduce the total capacitance value of the photo sensor element 10. In some embodiments, orthographic projections of at least some of the first openings 112 on the substrate 100 are located between orthographic projections of the photosensitive patterns 132 on the substrate 100. In the embodiment, the photosensitive patterns 132 are arranged in multiple columns, and the orthographic projections of at least some of the first openings 112 on the substrate 100 are located between the orthographic projections of two adjacent columns of the photosensitive patterns 132 on the substrate 100. In the embodiment, the orthographic projections of the photosensitive patterns 132 on the substrate 100 are respectively located on two opposite sides of orthographic projection of the scan line SL on the substrate 100.

In some embodiments, a material of the photosensitive layer 130 includes silicon-rich oxide. In some embodiments, the material of the photosensitive layer 130 includes an N-type semiconductor, an intrinsic semiconductor, and a P-type semiconductor.

An insulation layer PL1 is located on the data line DL, the source S, the drain D and the first electrode 110. In the embodiment, the insulation layer PL1 is partially located on the photosensitive layer 130 and has multiple via holes H3 exposing the photosensitive layer 130. Each of the via holes H3 overlaps one of the photosensitive patterns 132.

The second electrode 120 is located on the insulation layer PL1 and overlaps the first electrode 110 and the first openings 112. The photosensitive layer 130 is sandwiched between the first electrode 110 and the second electrode 120, and overlaps the first electrode 110 and the second electrode 120. In the embodiment, the second electrode 120 fills the via hole H3 and is connected to the photosensitive layer 130.

In the embodiment, a material of the second electrode 120 includes a transparent conductive material, such as indium tin oxide, indium zinc oxide, aluminum tin oxide, aluminum zinc oxide, indium germanium zinc oxide, or other suitable oxides, or a stacked layer of at least two of the above.

In the embodiment, the second electrode 120 includes multiple overlapped portions 122 and multiple connected portions 124. The overlapped portions 122 respectively overlap the photosensitive patterns 132. The connected portions 124 are connected to the overlapped portions 122, and some of the first openings 112 overlap the connected portions 124. In the embodiment, a shape of each of the connected portions 124 is X-shaped, and four end points of each of the connected portions 124 are respectively connected to four overlapped portions 122.

In the embodiment, the second electrode 120 includes multiple second openings 126. One of the second openings 126 is located between two adjacent connected portions 124. The second openings 126 may be configured to reduce a surface area of the second electrode 120 and reduce the total capacitance value of the photo sensor element 10. For example, a surface area of the second electrode 120 and the second openings 126 totals to R2. Since the surface area of the second openings 126 is greater than 0, the surface area of the second electrode 120 is less than R2.

Orthographic projections of at least some of the second openings 126 on the substrate 100 are located between orthographic projections of the connected portions 124 on the substrate 100. The second openings 126 and the first openings 112 are alternately disposed, thereby reducing the overlapped surface area of the first electrode 110 and the second electrode 120, so as to reduce the total capacitance value of the photo sensor element 10.

In some embodiments, the surface area of the second electrode 120 and the second openings 126 overlapping the first electrode 110 and the first openings 112 is 100% (that is, the surface area where R2 overlaps R1 is 100%), and an overlapped surface area of the second electrode 120 and the first electrode 110 is A, where 100%<A<30%. In some embodiments, the first electrode 110 does not have the first opening 112. In other words, a maximum surface area of the first electrode 110 is equal to R1. In some embodiments, the second electrode 120 does not have the second opening 126. In other words, a maximum surface area of the second electrode 120 is equal to R2.

In some embodiments, a proportion of the total surface area of the first electrode 110 and the first openings 112 occupied by the first openings 112 is B (that is, a proportion of the surface area of R1 occupied by the first openings 112 is B), where 0%<B<60%.

In some embodiments, a proportion of the total surface area of the second electrode 120 and the second openings 126 occupied by the second openings 126 is C (that is, a proportion of the surface area of R2 occupied by the second openings 126 is C), where 0%<C<60%.

In the embodiment, the second electrode 120 is electrically connected to the signal line CL through a via hole H4 that penetrates the insulation layer PL1. An insulation layer PL2 covers the second electrode 120.

Based on the above, the total capacitance value of the photo sensor element 10 may be reduced, thereby improving photosensitivity.

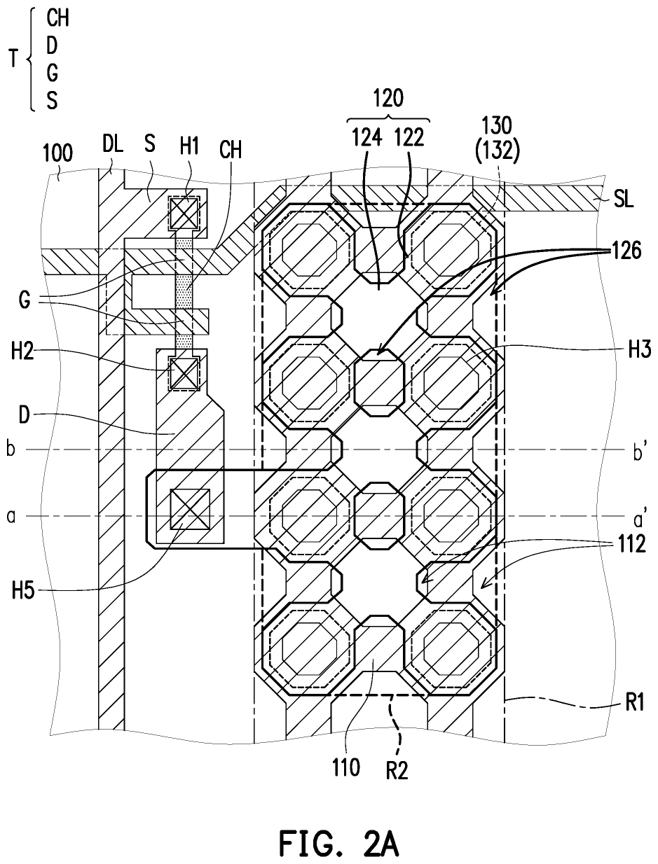

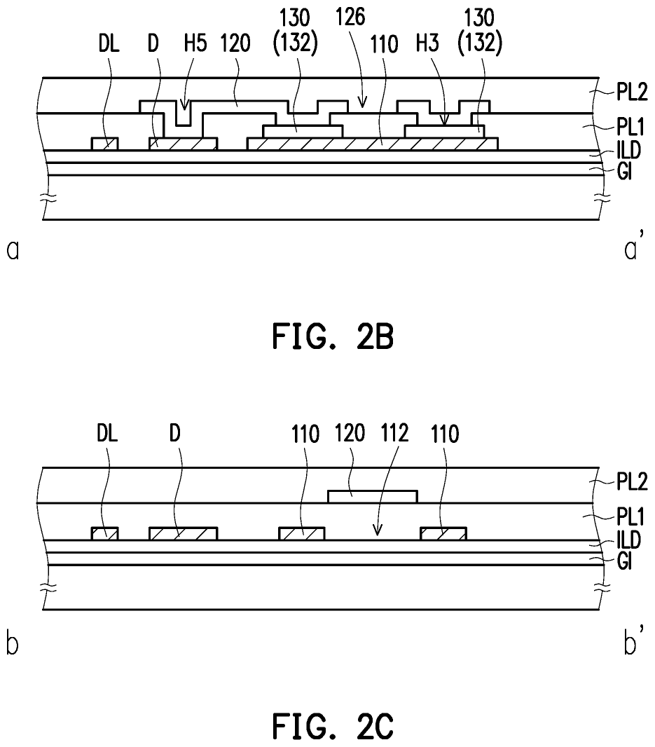

FIG. 2A is a schematic top view of a photo sensor element according to an embodiment of the disclosure. FIG. 2B is a schematic cross-sectional view taken along a line A-A′ in FIG. 2A. FIG. 2C is a schematic cross-sectional view taken along a line B-B′ in FIG. 2A.

With reference to FIGS. 2A, 2B and 2C, a photo sensor element 20 includes the substrate 100, the first electrode 110, the second electrode 120, and the photosensitive layer 130. In the embodiment, the photo sensor element 10 also includes the scan line SL, the data line DL, and the active element T.

The active element T is located on the substrate 100. The active element T includes the gate G, the semiconductor layer CH, the source S and the drain D. The gate G is electrically connected to the scan line SL. The semiconductor layer CH overlaps the gate G, and the gate insulation layer GI is sandwiched between the semiconductor layer CH and the gate G. In some embodiments, the semiconductor layer CH, the gate insulation layer GI, and the gate G are sequentially stacked on the substrate 100. The interlayer dielectric layer ILD is located on the gate G and the gate insulation layer GI. The source S and the drain D are located on the interlayer dielectric layer ILD. The source S is electrically connected to the data line DL and the semiconductor layer CH. In the embodiment, the source S is directly connected to the data line DL, and is electrically connected to the semiconductor layer CH through the via hole H1 that penetrates the interlayer dielectric layer ILD and the gate insulation layer GI. The drain D is electrically connected to the semiconductor layer CH and the second electrode 120. In the embodiment, the drain D is electrically connected to the semiconductor layer CH through the via hole H2 that penetrates the interlayer dielectric layer ILD and the gate insulation layer GI.

In the embodiment, the gate G and the scan line SL belong to the same conductive patterned layer, and are directly connected to each other, but the disclosure is not limited thereto. In the embodiment, the materials of the gate electrode G and the scan line SL include metals such as chromium, gold, silver, copper, tin, lead, hafnium, tungsten, molybdenum, neodymium, titanium, tantalum, aluminum, and zinc, alloys of the above metals, oxides of the above metals, nitrides of the above metals, or a combination of the above, or other conductive materials.

In the embodiment, the data line DL, the source S, the drain D and the first electrode 110 belong to the same conductive patterned layer, and a material of the layer includes metals such as chromium, gold, silver, copper, tin, lead, hafnium, tungsten, molybdenum, neodymium, titanium, tantalum, aluminum, zinc, alloys of the above metals, oxides of the above metal, nitrides of the above metal, or a combination of the above, or other conductive materials.

The first electrode 110 is located on the substrate 100 and has the multiple first openings 112. The first openings 112 may be configured to reduce the surface area of the first electrode 110 and reduce a total capacitance value of the photo sensor element 20. For example, the surface area of the first electrode 110 and the first openings 112 totals to R1. Since the surface area of the first openings 112 is greater than 0, the surface area of the first electrode 110 is less than R1. In the embodiment, the first electrode 110 and the drain D are separated from each other. In the embodiment, the first electrode 110 extends outward and is electrically connected to other voltages.

The photosensitive layer 130 is located on the first electrode 110. In some embodiments, the photosensitive layer 130 includes the multiple photosensitive patterns 132 that are separated from each other, whereby the separated photosensitive patterns 132 may reduce the total capacitance value of the photo sensor element 20. In some embodiments, the orthographic projections of the at least some of the first openings 112 on the substrate 100 are located between the orthographic projections of the photosensitive patterns 132 on the substrate 100. In the embodiment, the photosensitive patterns 132 are arranged in multiple columns, and the orthographic projections of the at least some of the first openings 112 on the substrate 100 are located between the orthographic projections of the two adjacent columns of the photosensitive patterns 132 on the substrate 100. In the embodiment, the orthographic projections of the photosensitive patterns 132 on the substrate 100 are respectively located on the two opposite sides of the orthographic projection of the scan line SL on the substrate 100.

In some embodiments, the material of the photosensitive layer 130 includes silicon-rich oxide. In some embodiments, the material of the photosensitive layer 130 includes a N-type semiconductor, an intrinsic semiconductor, and a P-type semiconductor.

The insulation layer PL1 is located on the data line DL, the source S, the drain D and the first electrode 110. In the embodiment, the insulation layer PL1 is partially located on the photosensitive layer 130 and has the multiple via holes H3 exposing the photosensitive layer 130. Each of the via holes H3 overlaps one of the photosensitive patterns 132. In the embodiment, the insulation layer PL1 also has a via hole H5 exposing the drain D.

The second electrode 120 is located on the insulation layer PL1 and overlaps the first electrode 110 and the first openings 112. The photosensitive layer 130 is sandwiched between the first electrode 110 and the second electrode 120, and overlaps the first electrode 110 and the second electrode 120. In the embodiment, the second electrode 120 fills the via hole H3 and is connected to the photosensitive layer 130. In the embodiment, the second electrode 120 fills the via hole H5 and is electrically connected to the drain D.

In the embodiment, the material of the second electrode 120 includes a transparent conductive material, such as indium tin oxide, indium zinc oxide, aluminum tin oxide, aluminum zinc oxide, indium germanium zinc oxide, or other suitable oxides, or a stacked layer of at least two of the above.

In the embodiment, the second electrode 120 includes the multiple overlapped portions 122 and the multiple connected portions 124. The overlapped portions 122 respectively overlap the photosensitive patterns 132. The connected portions 124 are connected to the overlapped portions 122, and the first openings 112 overlap the connected portions 124. In the embodiment, the shape of each of the connected portions 124 is X-shaped, and the four end points of each of the connected portions 124 are respectively connected to four overlapped portions 122.

In the embodiment, the second electrode 120 includes the multiple second openings 126. The second openings 126 may be configured to reduce the surface area of the second electrode 120 and reduce the total capacitance value of the photo sensor element 20. For example, the surface area of the second electrode 120 and the second openings 126 totals to R2. Since the surface area of the second openings 126 is greater than 0, the surface area of the second electrode 120 is less than R2.

The orthographic projections of the at least some of the second openings 126 on the substrate 100 are located between the orthographic projections of the connected portions 124 on the substrate 100. The second openings 126 and the first openings 112 are alternately disposed along the extension direction of the data line DL for example, and a portion of the one of the second openings 126 may overlap a portion of adjacent first opening 112, thereby reducing the overlapped surface area of the first electrode 110 and the second electrode 120, so as to reduce the total capacitance value of the photo sensor element 20.

In some embodiments, the surface area of the second electrode 120 and the second openings 126 overlapping the first electrode 110 and the first openings 112 is 100% (that is, the area where R1 overlaps R2 is 100%), and the overlapped surface area of the second electrode 120 and the first electrode 110 is A, where 100%<A<30%.

In some embodiments, the proportion of total surface area of the first electrode 110 and the first openings 112 occupied by the first openings 112 is B (that is, the proportion of the surface area of R1 occupied by the first openings 112 is B), where 0%<B<60%.

In some embodiments, the proportion of total surface area of the second electrode 120 and the second openings 126 occupied by the second openings 126 is C (that is, the proportion of the surface area of R2 occupied by the second openings 126 is C), where 0%<C<60%.

The insulation layer PL2 covers the second electrode 120.

Based on the above, the total capacitance value of the photo sensor element 20 may be reduced, thereby improving photosensitivity.

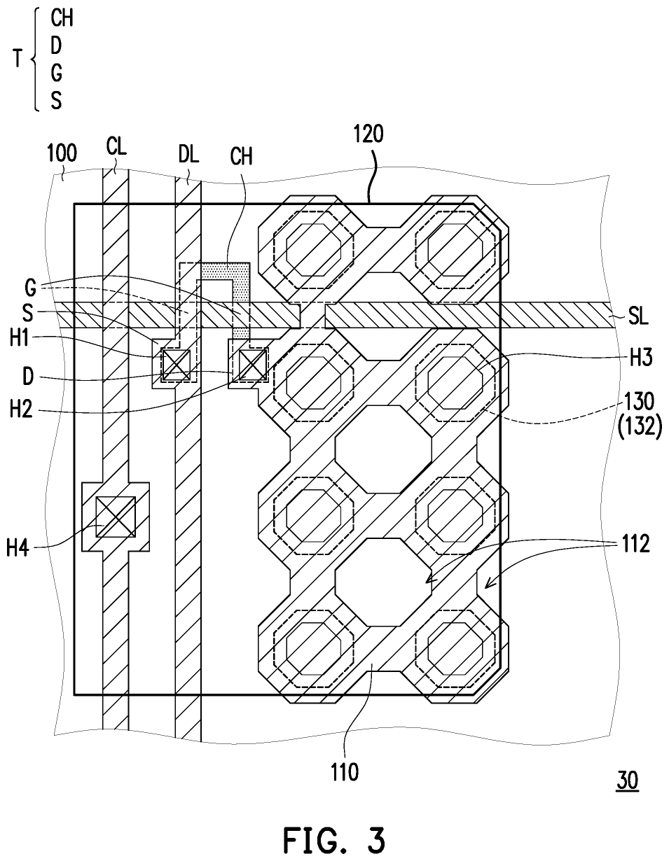

FIG. 3 is a schematic top view of a photo sensor element according to an embodiment of the disclosure. It should be noted here that the embodiment in FIG. 3 continues to use the element reference numerals and part of the content of the embodiment in FIG. 1A. The same or similar reference numerals are used to represent the same or similar elements, and description of the same technical content is omitted. Reference may be made to the foregoing embodiment for the description of the omitted parts, which will not be repeated here.

A difference between a photo sensor element 30 in FIG. 3 and the photo sensor element 10 in FIG. 1A including the second electrode 120 of the photo sensor element 30 is that in FIG. 3, the second electrode 120 does not have the via hole 126 that overlaps the first electrode 110.

With reference to FIG. 3, the photo sensor element 30 includes the substrate 100, the first electrode 110, the second electrode 120, and the photosensitive layer 130. The first electrode 110 is located on the substrate 100 and has the multiple first openings 112. The second electrode 120 overlaps the first electrode 110 and the first openings 112. The photosensitive layer 130 is sandwiched between the first electrode 110 and the second electrode 120, and overlaps the first electrode 110 and the second electrode 120.

Based on the above, the first openings 112 of the photo sensor element 30 may be configured to reduce the surface area of the first electrode 110 and reduce a total capacitance value of the photo sensor element 30.

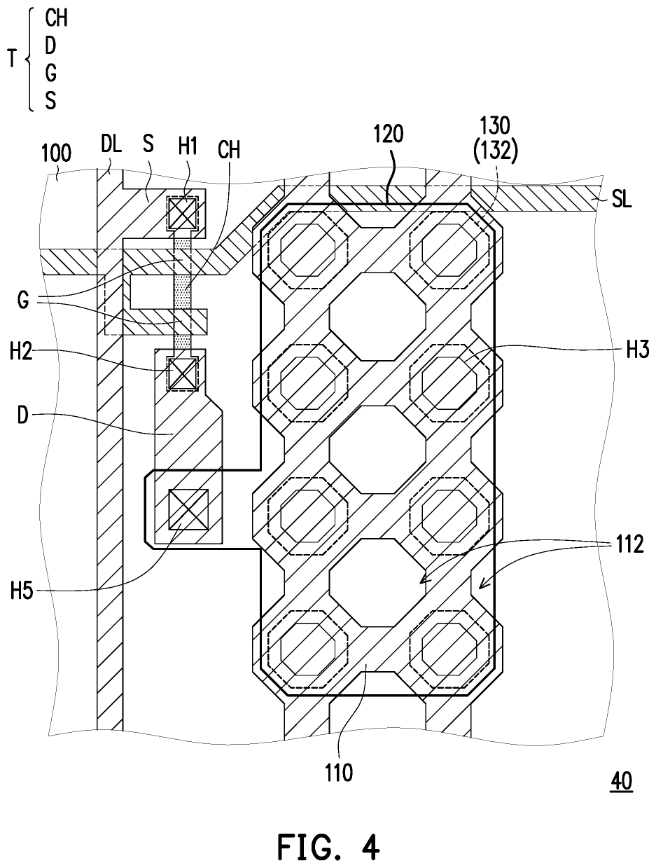

FIG. 4 is a schematic top view of a photo sensor element according to an embodiment of the disclosure. It should be noted here that the embodiment in FIG. 4 continues to use the element reference numerals and part of the content of the embodiment in FIG. 2A. The same or similar reference numerals are used to represent the same or similar elements, and description of the same technical content is omitted. Reference may be made to the foregoing embodiment for the description of the omitted parts, which will not be repeated here.

A difference between a photo sensor element 40 in FIG. 4 and the photo sensor element 10 in FIG. 2A including the second electrode 120 of the photo sensor element 40 is that in FIG. 4, the second electrode 120 does not have the via hole 126 that overlaps the first electrode 110.

With reference to FIG. 4, the photo sensor element 40 includes the substrate 100, the first electrode 110, the second electrode 120, and the photosensitive layer 130. The first electrode 110 is located on the substrate 100 and has the multiple first openings 112. The second electrode 120 overlaps the first electrode 110 and the first openings 112. The photosensitive layer 130 is sandwiched between the first electrode 110 and the second electrode 120, and overlaps the first electrode 110 and the second electrode 120.

Based on the above, the first openings 112 of the photo sensor element 40 may be configured to reduce the surface area of the first electrode 110 and reduce a total capacitance value of the photo sensor element 40.

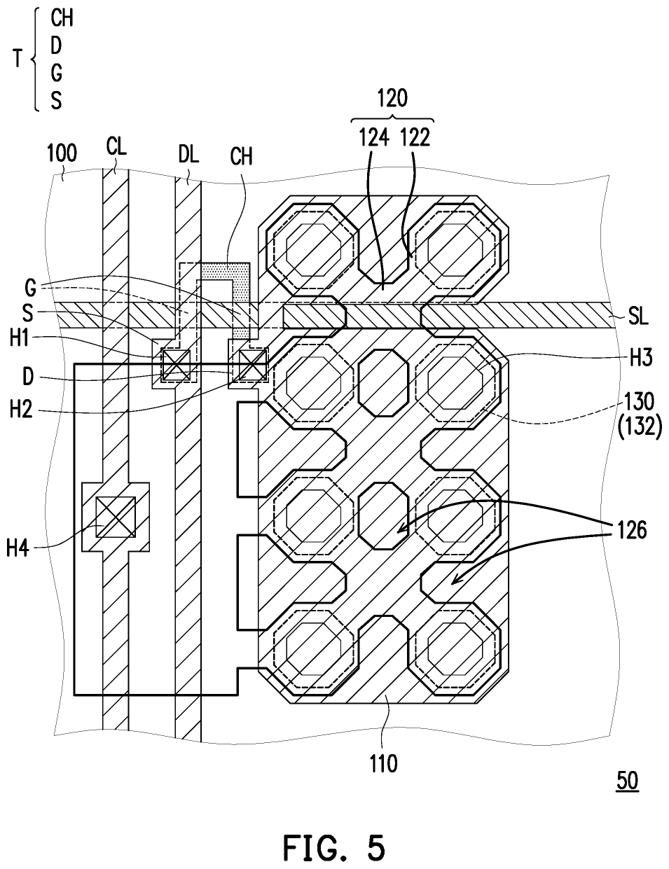

FIG. 5 is a schematic top view of a photo sensor element according to an embodiment of the disclosure. It should be noted here that the embodiment in FIG. 5 continues to use the element reference numerals and part of the content of the embodiment in FIG. 3. The same or similar reference numerals are used to represent the same or similar elements, and description of the same technical content is omitted. Reference may be made to the foregoing embodiment for the description of the omitted parts, which will not be repeated here.

Differences between a photo sensor element 50 in FIG. 5 and the photo sensor element 30 in FIG. 3 including the second electrode 120, the data line DL, the signal line CL, the source D, and the drain S of the photo sensor element 50, are that in FIG. 5, the second electrode 120, the data line DL, the signal line CL, the source S, and the drain D are belonging to a same conductive patterned layer, the first electrode 110 of the photo sensor element 50 is connected to the drain D of a switching element T, and the second electrode 120 is electrically connected to the signal line CL through the via hole H4.

With reference to FIG. 5, the photo sensor element 50 includes the substrate 100, the first electrode 110, the second electrode 120, and the photosensitive layer 130. The first electrode 110 is located on the substrate 100. The second electrode 120 overlaps the first electrode 110. The photosensitive layer 130 is sandwiched between the first electrode 110 and the second electrode 120, and overlaps the first electrode 110 and the second electrode 120.

The active element T includes the gate G, the semiconductor layer CH, the source S and the drain D. The gate G is electrically connected to the scan line SL. The semiconductor layer CH overlaps the gate G. The source S is electrically connected to the data line DL and the semiconductor layer CH. The drain D is electrically connected to the semiconductor layer CH and the first electrode 110. The first electrode 110 and the drain D belong to a same conductive patterned layer and are connected to each other.

In the embodiment, the second electrode 120 includes multiple overlapped portions 122 and multiple connected portions 124. The overlapped portions 122 respectively overlap the photosensitive patterns 132. The connected portions 124 are connected to the overlapped portions 122. In the embodiment, a shape of each of the connected portions 124 is X-shaped, and four end points of each of the connected portions 124 are respectively connected to four overlapped portions 122.

In the embodiment, a material of the second electrode 120 includes a transparent conductive material, such as indium tin oxide, indium zinc oxide, aluminum tin oxide, aluminum zinc oxide, indium germanium zinc oxide, or other suitable oxides, or a stacked layer of at least two of the above.

In the embodiment, the material of the first electrode 110 includes metals such as chromium, gold, silver, copper, tin, lead, hafnium, tungsten, molybdenum, neodymium, titanium, tantalum, aluminum, zinc, alloys of the above metals, oxides of the above metal, nitrides of the above metal, or a combination of the above, or other conductive materials.

Based on the above, the second openings 126 of the photo sensor element 50 may be configured to reduce the surface area of the second electrode 120 and reduce a total capacitance value of the photo sensor element 50.

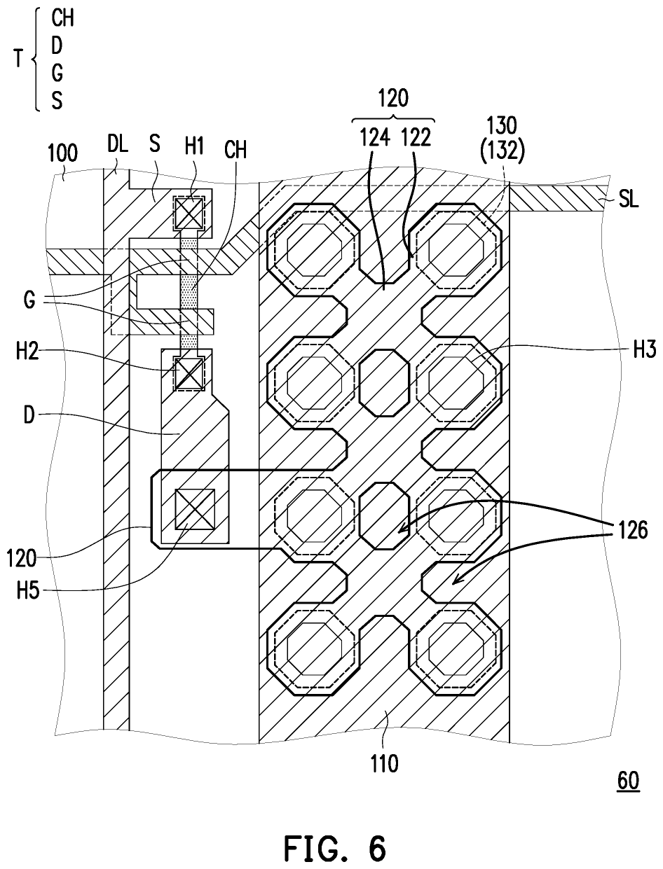

FIG. 6 is a schematic top view of a photo sensor element according to an embodiment of the disclosure. It should be noted here that the embodiment in FIG. 6 continues to use the element reference numerals and part of the content of the embodiment in FIG. 4. The same or similar reference numerals are used to represent the same or similar elements, and description of the same technical content is omitted. Reference may be made to the foregoing embodiment for the description of the omitted parts, which will not be repeated here.

Differences between a photo sensor element 60 in FIG. 6 and the photo sensor element 40 in FIG. 4 including the first electrode 110, the data line DL, the signal line CL, the source S, and the drain D of the photo sensor element 60 belonging to a same conductive patterned layer, the second electrode 120 of the photo sensor element 60 being connected to the drain D of the switching element T through via hole H5, and the first electrode 110 extending outward and is electrically connected to the other voltages (not shown), are in FIG. 6, the second electrode 120 includes multiple overlapped portions 122, multiple connected portions 124 and second openings 126.

With reference to FIG. 6, the photo sensor element 60 includes the substrate 100, the first electrode 110, the second electrode 120, and the photosensitive layer 130. The first electrode 110 is located on the substrate 100. The second electrode 120 overlaps the first electrode 110. The photosensitive layer 130 is sandwiched between the first electrode 110 and the second electrode 120, and overlaps the first electrode 110 and the second electrode 120.

The active element T includes the gate G, the semiconductor layer CH, the source S and the drain D. The gate G is electrically connected to the scan line SL. The semiconductor layer CH overlaps the gate G. The source S is electrically connected to the data line DL and the semiconductor layer CH. The drain D is electrically connected to the semiconductor layer CH and the second electrode 120. The first electrode 110 and the drain D belong to the same conductive patterned layer and are separated from each other.

In the embodiment, the second electrode 120 includes the multiple overlapped portions 122 and the multiple connected portions 124. The overlapped portions 122 respectively overlap the photosensitive patterns 132. The connected portions 124 are connected to the overlapped portions 122. In the embodiment, the shape of each of the connected portions 124 is X-shaped, and the four end points of each of the connected portions 124 are respectively connected to four overlapped portions 122.

In the embodiment, a material of the second electrode 120 includes a transparent conductive material, such as indium tin oxide, indium zinc oxide, aluminum tin oxide, aluminum zinc oxide, indium germanium zinc oxide, or other suitable oxides, or a stacked layer of at least two of the above.

In the embodiment, the material of the first electrode 110 includes metals such as chromium, gold, silver, copper, tin, lead, hafnium, tungsten, molybdenum, neodymium, titanium, tantalum, aluminum, zinc, alloys of the above metals, oxides of the above metal, nitrides of the above metal, or a combination of the above, or other conductive materials.

Based on the above, the second openings 126 of the photo sensor element 60 may be configured to reduce the surface area of the second electrode 120 and reduce a total capacitance value of the photo sensor element 60.

Although the disclosure has been disclosed with the foregoing exemplary embodiments, it is not intended to limit the disclosure. Any person skilled in the art can make various changes and modifications within the spirit and scope of the disclosure. Accordingly, the scope of the disclosure is defined by the claims appended hereto and their equivalents.

What is claimed is:

1. A photo sensor element, comprising:
a substrate;
a first electrode, located on the substrate and having a plurality of first openings;
a second electrode, overlapping the first electrode and the first openings; and
a photosensitive layer, sandwiched between the first electrode and the second electrode, and overlapping the first electrode and the second electrode.

2. The photo sensor element according to claim 1, wherein the photosensitive layer comprises a plurality of photosensitive patterns that are separated from each other, and orthographic projections of at least some of the first openings on the substrate are located between orthographic projections of the photosensitive patterns on the substrate.

3. The photo sensor element according to claim 2, wherein the photosensitive patterns are arranged in a plurality of columns, and orthographic projection of at least some of the first openings on the substrate are located between orthographic projections of two adjacent columns of the photosensitive patterns on the substrate.

4. The photo sensor element according to claim 2, wherein the second electrode comprises:
a plurality of overlapped portions, respectively overlapping the photosensitive patterns; and
a plurality of connected portions, connected to the overlapped portions, wherein at least some of the first openings overlap the connected portions.

5. The photo sensor element according to claim 4, wherein a shape of each of the connected portions is X-shaped, and four end points of each of the connected portions are respectively connected to one of the overlapped portions.

6. The photo sensor element according to claim 4, wherein the second electrode comprises a plurality of second openings, and orthographic projections of at least some of the second openings on the substrate are located between orthographic projections of the connected portions on the substrate.

7. The photo sensor element according to claim 6, wherein the second openings and the first openings are alternately disposed.

8. The photo sensor element according to claim 6, wherein a surface area of the second electrode and the second openings overlapping the first electrode and the first openings is 100%, and an overlapped surface area of the second electrode and the first electrode is A, where 100%<A<30%.

9. The photo sensor element according to claim 6, wherein a proportion of total surface area of the first electrode and the first openings occupied by the first openings is B, where 0%<B<60%.

10. The photo sensor element according to claim 6, wherein a proportion of total surface area of the second electrode and the second openings occupied by the second openings is C, where 0%<C<60%.

11. The photo sensor element according to claim 1, wherein a material of the photosensitive layer comprises silicon-rich oxide, or the material of the photosensitive layer comprises a N-type semiconductor, an intrinsic semiconductor, and a P-type semiconductor.

12. The photo sensor element according to claim 1, further comprising:
an active element, comprising:
a gate, electrically connected to a scan line;
a semiconductor layer, overlapping the gate;
a source, electrically connected to a data line and the semiconductor layer; and
a drain, electrically connected to the semiconductor layer and the second electrode, wherein the first electrode and the drain belong to a same conductive patterned layer and are separated from each other.

13. The photo sensor element according to claim 12, wherein the photosensitive layer comprises a plurality of photosensitive patterns that are separated from each other, and orthographic projections of the photosensitive patterns on the substrate are respectively located on two opposite sides of orthographic projection of the scan line on the substrate.

14. The photo sensor element according to claim 1, further comprising:
an active element, comprising:
a gate, electrically connected to a scan line;
a semiconductor layer, overlapping the gate;
a source, electrically connected to a data line and the semiconductor layer; and
a drain, electrically connected to the semiconductor layer and the second electrode, wherein the second electrode and the drain belong to a same conductive patterned layer and are connected to each other.

15. The photo sensor element according to claim 1, further comprising:
an active element, comprising:
a gate, electrically connected to a scan line;
a semiconductor layer, overlapping the gate;
a source, electrically connected to a data line and the semiconductor layer; and
a drain, electrically connected to the semiconductor layer, wherein the first electrode and the drain belong to a same conductive patterned layer, and the drain is directly connected to the first electrode.

16. The photo sensor element according to claim 15, wherein the photosensitive layer comprises a plurality of photosensitive patterns that are separated from each other, and orthographic projections of the photosensitive patterns on the substrate are respectively located on two opposite sides of orthographic projection of the scan line on the substrate.

17. The photo sensor element according to claim 1, further comprising:
an active element, comprising:
a gate, electrically connected to a scan line;
a semiconductor layer, overlapping the gate;
a source, electrically connected to a data line and the semiconductor layer; and
a drain, electrically connected to the semiconductor layer, wherein the second electrode and the drain belong to a same conductive patterned layer and are separated from each other.

18. The photo sensor element according to claim 1, wherein the first electrode comprises:
a plurality of overlapped portions, respectively overlapping a plurality of photosensitive patterns; and
a plurality of connected portions, connected to the overlapped portions, wherein a shape of each of the connected portions is X-shaped, and four end points of each of the connected portion are respectively connected to one of the overlapped portions.
